(19) United States
(12) Patent Application Publication
(10) Pub. No.: US 2025/0227911 A1
(43) Pub. Date: Jul. 10, 2025

(54) SEMICONDUCTOR DEVICE

(71) Applicant: Samsung Electronics Co., Ltd., Suwon-si (KR)

(72) Inventors: Chang-Su WOO, Suwon-si (KR); Jaewan CHANG, Suwon-si (KR); Sunmin MOON, Suwon-si (KR); Minho SONG, Suwon-si (KR)

(73) Assignee: Samsung Electronics Co., Ltd., Suwon-si (KR)

(21) Appl. No.: 18/785,656

(22) Filed: Jul. 26, 2024

(30) Foreign Application Priority Data
Jan. 9, 2024 (KR) 10-2024-0003526

(51) Int. Cl. H10B 12/00

(52) U.S. Cl. CPC H10B 12/315; H10B 12/03

(57) ABSTRACT

A semiconductor device may include a capacitor. The capacitor may include a bottom electrode, a first dielectric layer on the bottom electrode, a first insertion layer on the first dielectric layer, a second dielectric layer on the first insertion layer, a second insertion layer on the second dielectric layer, a third dielectric layer on the second insertion layer, and a top electrode on the third dielectric layer. At least one of the first to third dielectric layers may include a first element, and at least one of the first insertion layer or the second insertion layer may include both the first element and a second element, the second element different from the first element.

### CROSS-REFERENCE TO RELATED APPLICATIONS

This U.S. non-provisional patent application claims priority under 35 U.S.C. § 119 to Korean Patent Application No. 10-2024-0003526, filed on Jan. 9, 2024, in the Korean Intellectual Property Office, the entire contents of which are hereby incorporated by reference.

### BACKGROUND

The present inventive concepts relate to semiconductor devices, and in particular, to semiconductor devices including a capacitor.

Due to their small-sized, multifunctional, and/or low-cost characteristics, semiconductor devices are being esteemed as important elements in the electronic industry. The semiconductor devices are classified into a semiconductor memory device for storing data, a semiconductor logic device for processing data, and a hybrid semiconductor device including both of memory and logic elements.

As integration densities of the semiconductor devices increase, it is necessary to realize a capacitor having sufficiently high capacitance in a limited area. The capacitance of the capacitor varies in proportion to the surface area of an electrode and the dielectric constant of a dielectric layer, and inversely with the equivalent oxide thickness of the dielectric layer. Recently, various studies are being conducted to increase the capacitance of the capacitor.

### SUMMARY

Some example embodiments of the inventive concepts provide a semiconductor device configured to exhibit a reduced, minimized, or prevented leakage current.

According to some example embodiments of the inventive concepts, a semiconductor device may include a capacitor. The capacitor may include a bottom electrode, a first dielectric layer on the bottom electrode, a first insertion layer on the first dielectric layer, a second dielectric layer on the first insertion layer, a second insertion layer on the second dielectric layer, a third dielectric layer on the second insertion layer, and a top electrode on the third dielectric layer. At least one of the first to third dielectric layers may include a first element, and at least one of the first insertion layer or the second insertion layer may include both the first element and a second element, the second element different from the first element.

According to some example embodiments of the inventive concepts, a semiconductor device may include a substrate, word lines in the substrate, a first impurity region in the substrate at a side of the word lines, a second impurity region in the substrate and between the word lines, a bit line connected to the second impurity region and on the substrate where the bit line crosses the word lines, a conductive contact connected to the first impurity region and on the substrate, a bottom electrode on the conductive contact, a dielectric layer on the bottom electrode, a top electrode on the dielectric layer, and a supporting pattern in contact with an upper side surface of the bottom electrode. The dielectric layer may include first to third sub-dielectric layers that are sequentially stacked and first and second insertion layers, the first and second insertion layers between separate, respective sets of adjacent sub-dielectric layers of the first to third sub-dielectric layers. At least one of the first to third sub-dielectric layers may include a first element, and at least one of the first insertion layer or the second insertion layer may include the first element. Each of the first and second insertion layers may have a thickness ranging from 0.3 Å to 10 Å.

According to some example embodiments of the inventive concepts, a semiconductor device may include a substrate, conductive contacts on the substrate, and capacitors on the conductive contacts. Each of the capacitors may include a bottom electrode, a dielectric layer on the bottom electrode, and a top electrode on the dielectric layer. The dielectric layer may include first to third sub-dielectric layers that are sequentially stacked and first and second insertion layers, the first and second insertion layers between separate, respective sets of adjacent sub-dielectric layers of the first to third sub-dielectric layers. Each of the first and second insertion layers may have at least one of tetragonal crystal structure or orthorhombic crystal structure.

### BRIEF DESCRIPTION OF THE DRAWINGS

FIG. 1 is a sectional view illustrating a semiconductor device according to some example embodiments of the inventive concepts.

FIG. 2 is a flow chart illustrating a method of fabricating a semiconductor device, according to some example embodiments of the inventive concepts.

FIG. 3 is a plan view illustrating a semiconductor device according to some example embodiments of the inventive concepts.

FIG. 4 is a sectional view taken along a line A-A′ of FIG. 3 according to some example embodiments of the inventive concepts.

FIG. 5A is an enlarged sectional view illustrating a portion ‘P1’ of FIG. 4 according to some example embodiments of the inventive concepts.

FIG. 5B is a plan view of the semiconductor device of FIG. 4, taken along a line E-E′ of FIG. 4 according to some example embodiments of the inventive concepts.

FIGS. 6A, 6B, 6D, 6E, 6F, and 6G are sectional views sequentially illustrating a method of fabricating a semiconductor device, which has the section of FIG. 4, according to some example embodiments of the inventive concepts.

FIG. 6C is a plan view illustrating a method of fabricating a semiconductor device, which has the plan view of FIG. 3, according to some example embodiments of the inventive concepts.

FIG. 7 is a sectional view taken along the line A-A′ of FIG. 3 according to some example embodiments of the inventive concepts.

FIG. 8 is a sectional view taken along the line A-A′ of FIG. 3 according to some example embodiments of the inventive concepts.

FIG. 9 is a sectional view illustrating a semiconductor device according to some example embodiments of the inventive concepts.

FIG. 10 is a sectional view illustrating a semiconductor device according to some example embodiments of the inventive concepts.

FIG. 11 is an enlarged sectional view illustrating a portion ‘P2’ of FIGS. 7, 8, 9, and 10, according to some example embodiments of the inventive concepts.

FIG. 12 is a plan view illustrating a semiconductor device according to some example embodiments of the inventive concepts.

FIG. 13 is a sectional view taken along lines C-C′ and D-D′ of FIG. 12 according to some example embodiments of the inventive concepts.

FIG. 14 is a perspective view illustrating a three-dimensional semiconductor memory device according to some example embodiments of the inventive concepts.

FIG. 15 is a sectional view taken along a line F-F′ of FIG. 14, according to some example embodiments of the inventive concepts.

FIG. 16 is a sectional view illustrating a semiconductor device according to some example embodiments of the inventive concepts.

### DETAILED DESCRIPTION

Example embodiments of the inventive concepts will now be described more fully with reference to the accompanying drawings, in which some example embodiments are shown. The drawings and description are to be regarded as illustrative in nature and not restrictive. Like reference numerals designate like elements throughout the specification. Size and thickness of each constituent element in the drawings are arbitrarily illustrated for better understanding and ease of description, the following embodiments are not limited thereto.

Throughout the specification, the term “connected” does not mean only that two or more constituent components are directly connected, but may also mean that two or more constituent components are indirectly connected through another constituent component. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is referred to as being “above” or “on” a reference element, it can be positioned above or below the reference element, and it is not necessarily referred to as being positioned “above” or “on” in a direction opposite to gravity.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element is referred to as being the same as another element, it should be understood that an element or a value is the same as another element within a desired manufacturing or operational tolerance range (e.g., ±10%).

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

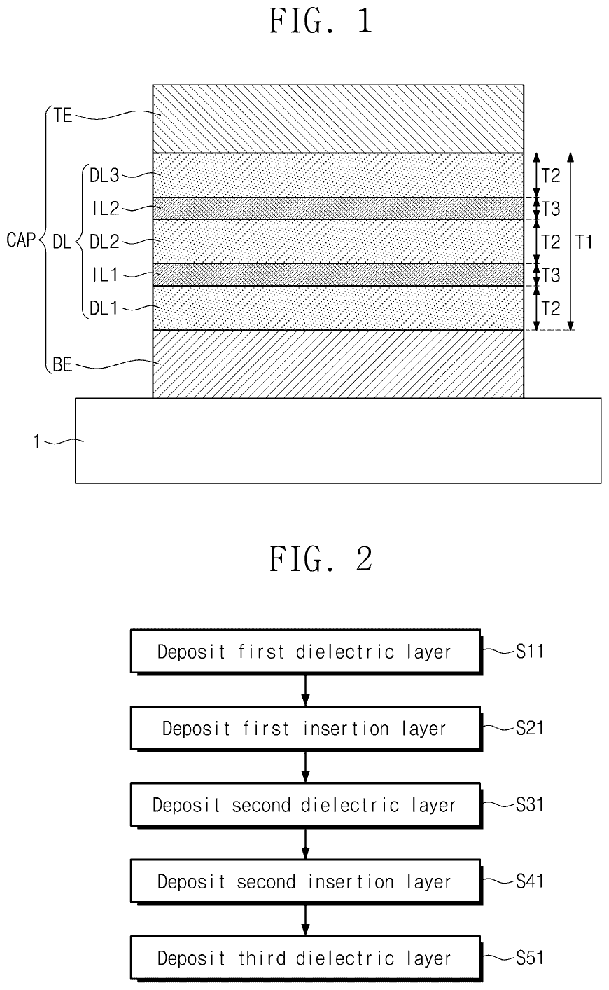

FIG. 1 is a sectional view illustrating a semiconductor device according to some example embodiments of the inventive concepts. FIG. 2 is a flow chart illustrating a method of fabricating a semiconductor device, according to some example embodiments of the inventive concepts.

Referring to FIG. 1, a lower layer 1 may be provided. The lower layer 1 may be a semiconductor layer, an insulating layer, or a conductive layer. The lower layer 1 may include a semiconductor substrate, an interlayer insulating layer, and/or a contact plug. A capacitor CAP may be provided on the lower layer 1. In the case where the semiconductor device is a memory device, the capacitor CAP may be used as a data storage element of each memory cell. The capacitor CAP may include a bottom electrode BE, a dielectric layer DL, and a top electrode TE sequentially stacked, for example such that the dielectric layer DL is on the bottom electrode BE and the top electrode TE is on the dielectric layer DL such that the dielectric layer DL is between the bottom electrode BE and the top electrode TE.

The dielectric layer DL may be disposed on the bottom electrode BE. The dielectric layer DL may include a first sub-dielectric layer DL1, a second sub-dielectric layer DL2, and a third sub-dielectric layer DL3 sequentially stacked. The first to third sub-dielectric layers DL1, DL2, and DL3 may be spaced apart from each other. The first sub-dielectric layer DL1 may be in contact with the bottom electrode BE. However, the inventive concepts are not limited to this example, and an additional layer may be further disposed between the first sub-dielectric layer DL1 and the bottom electrode BE. The third sub-dielectric layer DL3 may be in contact with the top electrode TE. However, the inventive concepts are not limited to this example, and an additional layer may be further disposed between the third sub-dielectric layer DL3 and the top electrode TE. In some example embodiments, although not illustrated, the dielectric layer DL may include four or more sub-dielectric layers. In the present specification, the ‘sub-dielectric layer’ may be referred to as a ‘dielectric layer’.

A first insertion layer IL1 and a second insertion layer IL2 may be respectively interposed between the first to third sub-dielectric layers DL1, DL2, and DL3, for example such that the first insertion layer IL1 and the second insertion layer IL2 may be between separate, respective sets of adjacent sub-dielectric layers of the first to third sub-dielectric layers DL1, DL2, and DL3. The first insertion layer IL1 may be interposed between the first sub-dielectric layer DL1 and the second sub-dielectric layer DL2. The second insertion layer IL2 may be interposed between the second sub-dielectric layer DL2 and the third sub-dielectric layer DL3. The first insertion layer IL1 and the second insertion layer IL2 may be disposed to be spaced apart from each other. The second sub-dielectric layer DL2 may be interposed between the first insertion layer IL1 and the second insertion layer IL2. In some example embodiments, although not illustrated, three or more insertion layers may be disposed in the dielectric layer DL.

The dielectric layer DL may have a first thickness T1 ranging from 10 Å to 100 Å. Each of the first to third sub-dielectric layers DL1, DL2, and DL3 may have a second thickness T2 ranging from 1 Å to 60 Å. The second thickness T2 of the first to third sub-dielectric layers DL1, DL2, and DL3 may be equal to or different from each other. Each of the first and second insertion layers IL1 and IL2 may have a third thickness T3 ranging from 0.3 Å to 10 Å. The third thickness T3 of the first and second insertion layers IL1 and IL2 may be equal to or different from each other. The third thickness T3 of the first and second insertion layers IL1 and IL2 may be smaller than or equal to the second thickness T2 of the first to third sub-dielectric layers DL1, DL2, and DL3. As shown, the first thickness T1 of the dielectric layer DL may be equal to or greater than a sum of the respective second thicknesses T2 of the first to third sub-dielectric layers DL1, DL2, and DL3 and the respective third thicknesses T3 of the first and second insertion layers IL1 and IL2.

In some example embodiments, at least one of the first to third sub-dielectric layers DL1, DL2, and DL3 may include a first element. In some example embodiments, each of the first to third sub-dielectric layers DL1, DL2, and DL3 may include the first element. The first element may include one of Zr, Hf, Si, Ti, Nb, Ba, Mg, Lu, Ta, Ca, Ga, Y, Al, La, Ge, Sr, or Gd. In some example embodiments, the first element may be hafnium (Hf) or zirconium (Zr). At least one of the first to third sub-dielectric layers DL1, DL2, and DL3 may include an oxide layer containing the first element. For example, at least one of the first to third sub-dielectric layers DL1, DL2, and DL3 may be formed of or include hafnium oxide, zirconium oxide, or hafnium-zirconium oxide. However, the inventive concepts are not limited to the above materials. In some example embodiments, each of the first to third sub-dielectric layers DL1, DL2, and DL3 may include an oxide layer containing the first element. For example, each of the first to third sub-dielectric layers DL1, DL2, and DL3 may be formed of or include hafnium oxide, zirconium oxide, or hafnium-zirconium oxide. However, the inventive concepts are not limited to the above materials.

In some example embodiments, at least one of the first insertion layer IL1 or the second insertion layer IL2 may include the first element. In some example embodiments, each of the first and second insertion layers IL1 and IL2 may include the first element. In some example embodiments, the first element, which is included in the first and second insertion layers IL1 and IL2, may be hafnium (Hf) or zirconium (Zr). For example, at least one of the first or second insertion layers IL1 or IL2 may be formed of or include at least one of zirconium oxide, hafnium oxide, or hafnium-zirconium oxide. For example, each of the first and second insertion layers IL1 and IL2 may be formed of or include at least one of zirconium oxide, hafnium oxide, or hafnium-zirconium oxide.

In some example embodiments, at least one of the first insertion layer IL1 or the second insertion layer IL2 may include a second element. In some example embodiments, each of the first and second insertion layers IL1 and IL2 may include the second element. In some example embodiments, at least one of the first insertion layer IL1 or the second insertion layer IL2 may include both the first element and the second element. In some example embodiments, each of the first and second insertion layers IL1 and IL2 may include both the first element and the second element. For example, the second element may be one of Al, Zr, Hf, Si, Ba, Mg, Ca, Ga, Y, La, B, Be, Ge, Sr, or Gd. In some example embodiments, the second element may be aluminum (Al). At least one of the first or second insertion layers IL1 or IL2 may be an oxide layer that is doped with the second element. For example, at least one of the first or second insertion layers IL1 or IL2 may include one of zirconium oxide (ZrₓO₂) doped with aluminum (Al), hafnium oxide (HfO₂) doped with aluminum (Al), Al_{y}ZrₓO₂, or Al_{y}HfₓO₂ (0<x≤1 and 0<y≤1). In some example embodiments, each of the first and second insertion layers IL1 and IL2 may be an oxide layer that is doped with the second element. For example, each of the first and second insertion layers IL1 and IL2 may include one of zirconium oxide (ZrₓO₂) doped with aluminum (Al), hafnium oxide (HfₓO₂) doped with aluminum (Al), Al_{y}ZrₓO₂, or Al_{y}HfₓO₂ (0<x≤1 and 0<y≤1). The content of aluminum (Al), which is doped in each of the first and second insertion layers IL1 and IL2, may range from 0.1 at % to 70 at %, in particular, from 20 at % to 40 at %. However, the inventive concepts are not limited to the above materials. In some example embodiments, where at least one of the first insertion layer IL1 or the second insertion layer IL2 includes the second element (e.g., in addition to including the first element), for example where each of the first and second insertion layers IL1 and IL2 includes the second element (e.g., in addition to including the first element), an energy band gap of the first and/or second insertion layers IL1 and/or IL2, the dielectric layer DL, the capacitor CAP, or any combination thereof may be increased. As a result, based on providing the first and second insertion layers IL1 and IL2 in the dielectric layer DL, it may be possible to configure the capacitor CAP to reduce, minimize, or prevent a leakage current passing through the dielectric layer DL. As a result, based on the capacitor CAP including a dielectric layer DL that includes the first to third sub-dielectric layers DL1 to DL3 and the first and second insertion layers IL1 and IL2, where at least one (e.g., each) of the first to third sub-dielectric layers DL1 to DL3 include a first element and at least one (e.g., each) of the first and/or second insertion layers IL1 and IL2 include both the first element and a different, second element according to some example embodiments, the capacitor CAP may exhibit reduced, minimized, or prevented leakage current passing through the dielectric layer DL and thus may exhibit improved performance (e.g., improved capacitance, reduced signal loss due to leakage current, reduced power consumption due to leakage current, etc.), may exhibit improved reliability of a semiconductor device including the capacitor CAP (e.g., reduced risk of device failure due to leakage current through the dielectric layer DL), or the like.

The dielectric layer DL may be used as a dielectric layer of the capacitor CAP of a dynamic random-access memory (DRAM) device, as shown in FIG. 1. In some example embodiments, the dielectric layer DL may be used as a gate insulating layer of a transistor with a high-k metal gate electrode or as a gate insulating layer of a cell transistor of a FLASH memory device, and in this case, it may be possible to reduce, minimize, or prevent a leakage current in the semiconductor device, thereby improving the functionality (e.g., transistor functionality, signal quality, capacitance, power consumption efficiency, etc.) of the semiconductor device.

The first to third sub-dielectric layers DL1, DL2, and DL3 may have the same crystal structure or may have different crystal structures from each other. For example, each of the first to third sub-dielectric layers DL1, DL2, and DL3 may have a tetragonal crystal structure or an orthorhombic crystal structure. However, the inventive concepts are not limited to this example, and the first to third sub-dielectric layers DL1, DL2, and DL3 may have various crystal structures.

In some example embodiments, each of the first and second insertion layers IL1 and IL2 may have a tetragonal crystal structure or an orthorhombic crystal structure. In some example embodiments, including example embodiments where the first and second insertion layers IL1 and IL2 contain the first element included in the first to third sub-dielectric layers DL1, DL2, and DL3 with high dielectric constants, the first and second insertion layers IL1 and IL2 may have a crystal structure. Accordingly, it may be possible to prevent a crystallinity degradation issue (e.g., crystallinity deterioration issue) and the consequent issue of lowering dielectric constant from occurring in the first and second insertion layers IL1 and IL2, or such crystallinity degradation and the consequent lowering issue of dielectric constant from occurring in the first and second insertion layers IL1 and IL2 may be reduced or minimized, based on the first and second insertion layers IL1 and IL2 being formed in the dielectric layer DL through a deposition process, for example where at least one (e.g., each) of the first and second insertion layers IL1 and IL2 include both the first element included in the first to third sub-dielectric layers DL1, DL2, and DL3 with high dielectric constants and further include the second element and further have a crystal structure, for example a tetragonal crystal structure or an orthorhombic crystal structure. As a result, based on the capacitor CAP including a dielectric layer DL that includes the first to third sub-dielectric layers DL1 to DL3 and the first and second insertion layers IL1 and IL2, where the first to third sub-dielectric layers DL1, DL2, and DL3 may have various crystal structures and high dielectric constants and each of the first and second insertion layers IL1 and IL2 have a tetragonal crystal structure or an orthorhombic crystal structure, the likelihood of crystallinity degradation (e.g., crystallinity deterioration) and consequent lowering of dielectric constant in the first and second insertion layers IL1 and IL2 may be reduced, minimized, or prevented. As a result, the reliability and/or yield of the capacitor CAP and semiconductor devices including same may be improved due to the reduced likelihood of process defects resulting from such crystallinity degradation and consequent lowering of dielectric constant in the first and second insertion layers IL1 and IL2. For example, the capacitor CAP and semiconductor device including same may be configured to exhibit reduced leakage current through the dielectric layer thereof based on including the first and second insertion layers IL1 and IL2 in addition to the first to third sub-dielectric layers DL1 to DL3 without compromising the dielectric constant of the insertion layers IL1 and IL2 due to crystallinity degradation based on the first and second insertion layers IL1 and IL2 being formed in the dielectric layer DL through a deposition process.

The crystal structure of the layers and the structure of the dielectric layer DL may be examined using, for example, one of transmission electron microscopy (TEM), grazing incidence x-ray diffraction (GIXRD), energy dispersive spectrometer (EDS), energy dispersive x-ray spectroscopy (EDX), electron energy loss spectroscopy (EELS), and secondary ion mass spectrometry (SIMS) methods.

Each of the bottom and top electrodes BE and TE may be formed of or include at least one of conductive materials (e.g., doped silicon, doped silicon germanium, metallic materials, metal nitride materials, conductive oxide materials, and metal silicide materials). For example, each of the bottom and top electrodes BE and TE may be formed of or include at least one of VN, TiN, NbN, MON, TaN, Ru, RuO₂, Pt, Ir, SrRuO₃, W, or WN. Each of the bottom and top electrodes BE and TE may be a single layer, which is made of a single material, or a composite layer including two or more materials.

A process of fabricating the capacitor CAP of FIG. 1 is as follows:

Referring to FIGS. 1 and 2, the bottom electrode BE may be formed on the lower layer 1. The dielectric layer DL may be formed by sequentially depositing the first sub-dielectric layer DL1, the first insertion layer IL1, the second sub-dielectric layer DL2, the second insertion layer IL2, and the third sub-dielectric layer DL3 on the bottom electrode BE using deposition processes (e.g., an atomic layer deposition (ALD)).

The first sub-dielectric layer DL1 may be deposited on the bottom electrode BE to have the second thickness T2 (in a first step S11). For example, the first sub-dielectric layer DL1 may be formed of or include at least one of zirconium oxide, hafnium oxide, or hafnium-zirconium oxide. In some example embodiments, a first Zr layer, which is a single atomic layer, may be deposited by feeding and adsorbing a Zr precursor on a surface of the bottom electrode BE. Inert gas (e.g., including Ar) may be used to purge a non-adsorption fraction of the Zr precursor. Oxygen-containing gas (e.g., O₂, O₃, H₂O, and H₂O₃) may be supplied to combine oxygen atoms with the first Zr layer. The first sub-dielectric layer DL1 with a desired thickness (e.g., T2) may be formed by performing the afore-described process cycle several times.

The first insertion layer IL1 may be deposited on the first sub-dielectric layer DL1 to have the third thickness T3 (in a second step S21). The first insertion layer IL1 may be formed of or include the first element (e.g., zirconium (Zr) or hafnium (Hf)), which is included in the first sub-dielectric layer DL1. For example, the first insertion layer IL1 may be doped with the second element through an absorption controlled atomic layer deposition (ACALD) process.

In some example embodiments, a second Zr layer, which is a single atomic layer, may be deposited by feeding and adsorbing a Zr precursor on a surface of the first sub-dielectric layer DL1. An inert gas (e.g., including Ar atoms) may be used to purge a non-adsorption fraction of the Zr precursor. Next, atoms of the second element to be doped may be adsorbed on a surface of the second Zr layer, and then, an inert gas (e.g., including Ar atoms) may be used to purge non-adsorbed atoms of the second element. Oxygen-containing gas (e.g., O₂, O₃, H₂O, and H₂O₃) may be supplied to combine oxygen atoms with the second Zr layer doped with the second element. Next, the first insertion layer IL1, which has a desired thickness (e.g., T3), may be formed by performing the afore-described process cycle several times.

The second sub-dielectric layer DL2 may be deposited on the first insertion layer IL1 to have the second thickness T2 (in a third step S31). For example, the second sub-dielectric layer DL2 may be formed of or include at least one of zirconium oxide, hafnium oxide, or hafnium-zirconium oxide. The third step S31 may be the same as the first step S11, which is performed to form the first sub-dielectric layer DL1.

The second insertion layer IL2 may be deposited on the second sub-dielectric layer DL2 to have the third thickness T3 (in a fourth step S41). The fourth step S41 may be the same as the second step S21, which is performed to form the first insertion layer IL1. A concentration and distribution of the second element, which is doped in the first and second insertion layers IL1 and IL2, may be controlled by adjusting the number and time of the process of adsorbing the atoms of the second element and the repetition number of the cycle of an atomic layer deposition (ALD).

The third sub-dielectric layer DL3 may be deposited on the second insertion layer IL2 to have the second thickness T2 (in a fifth step S51). For example, the third sub-dielectric layer DL3 may be formed of or include at least one of zirconium oxide, hafnium oxide, or hafnium-zirconium oxide. The fifth step S51 may be the same as the first step S11, which is performed to form the first sub-dielectric layer DL1.

The first to fifth steps S11 to S51 may be performed under temperature of 200° C. to 400° C. and pressure of 100 Pa to 300 Pa. The first, third, and fifth steps S11, S31, and S51, which are performed to form the first to third sub-dielectric layers DL1, DL2, and DL3, may include a process of depositing a hafnium oxide layer and a process of depositing a zirconium oxide layer. The first, third, and fifth steps S11, S31, and S51 may not include a process of doping the second element. In the first, third, and fifth steps S11, S31, and S51, a composition ratio of hafnium oxide and zirconium oxide in each of the first to third sub-dielectric layers DL1, DL2, and DL3 may be controlled by adjusting the deposition thicknesses of the hafnium oxide layer and the zirconium oxide layer. Next, the semiconductor device, which has the section of FIG. 1, may be formed by forming the top electrode TE on the dielectric layer DL.

The capacitor CAP may be provided to have various shapes. Hereinafter, this will be described in more detail.

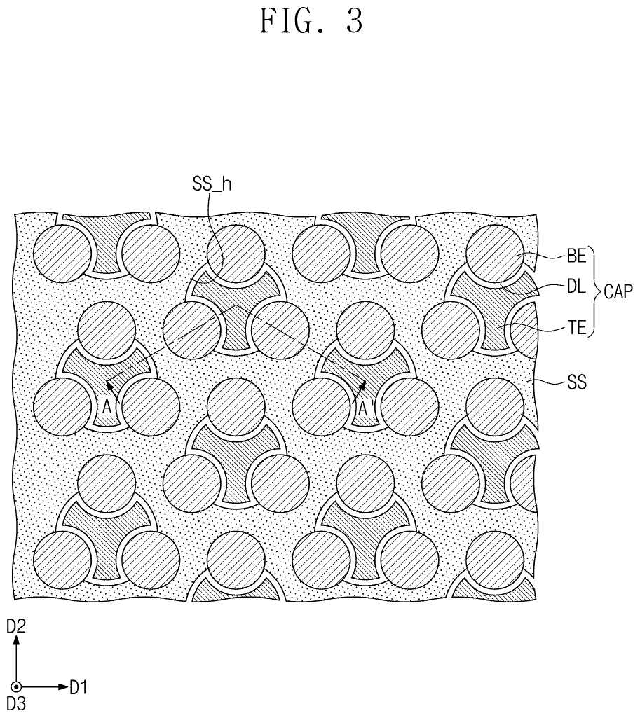

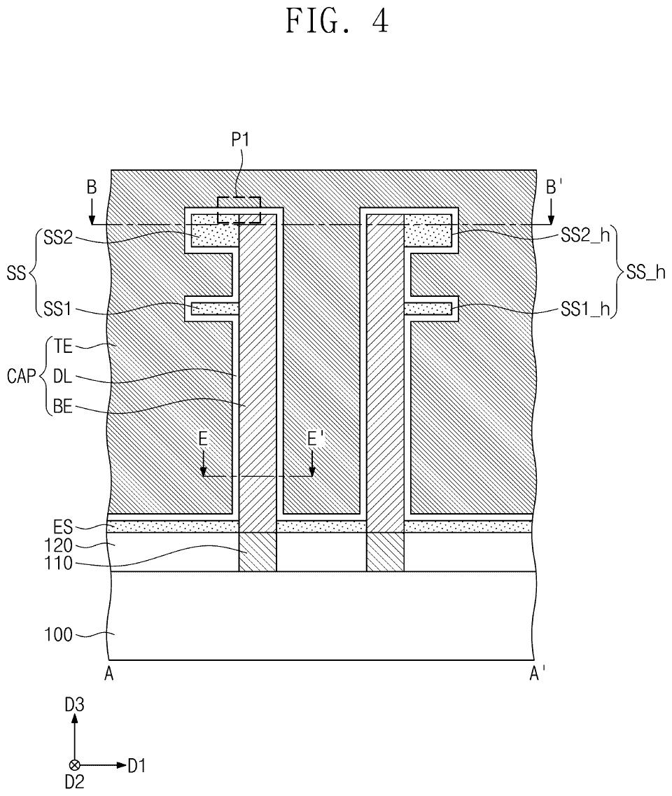

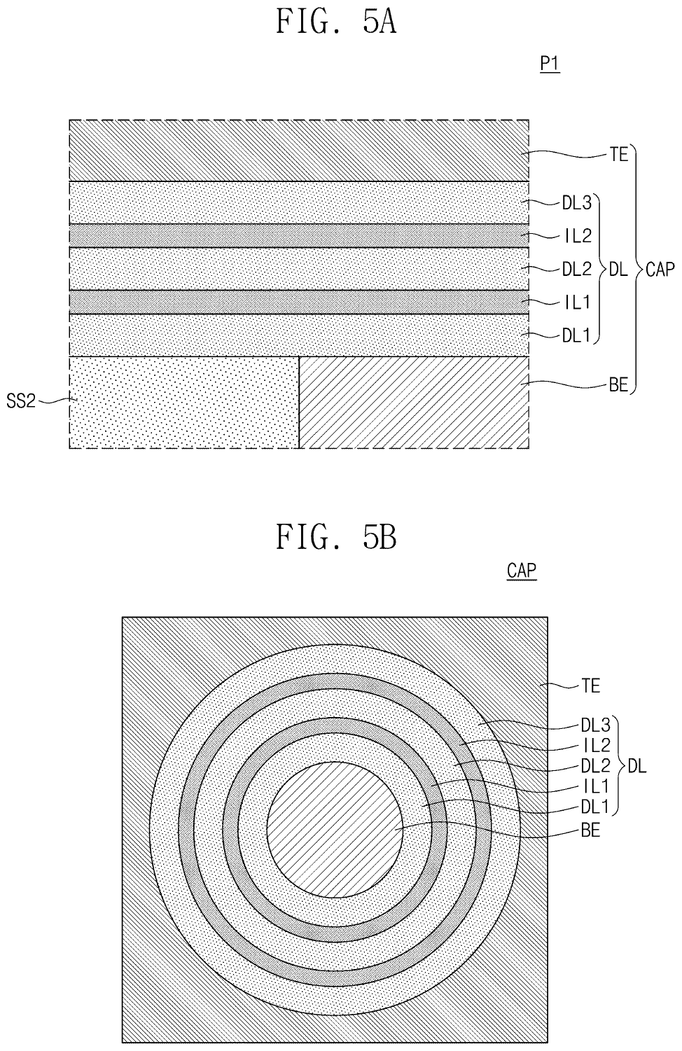

FIG. 3 is a plan view illustrating a semiconductor device according to some example embodiments of the inventive concepts. FIG. 4 is a sectional view taken along a line A-A′ of FIG. 3 according to some example embodiments of the inventive concepts. FIG. 5A is an enlarged sectional view illustrating a portion ‘P1’ of FIG. 4 according to some example embodiments of the inventive concepts. FIG. 3 corresponds to a plan view of the semiconductor device, taken along a line B-B′ of FIG. 4. FIG. 5B is a plan view of the semiconductor device of FIG. 4, taken along a line E-E′ of FIG. 4 according to some example embodiments of the inventive concepts.

Referring to FIGS. 3 and 4, a first substrate 100 may be provided. The first substrate 100 may be a semiconductor substrate. In some example embodiments, the first substrate 100 may be a silicon substrate, a germanium substrate, or a silicon-germanium substrate. An interlayer insulating layer 120 may be disposed on the first substrate 100. In some example embodiments, the interlayer insulating layer 120 may be formed of or include at least one of silicon nitride, silicon oxide, or silicon oxynitride. Conductive contacts 110 may be disposed in the interlayer insulating layer 120. The conductive contacts 110 may be provided to penetrate the interlayer insulating layer 120 and may be electrically connected to the first substrate 100. The conductive contacts 110 may include at least one of a doped polysilicon pattern, a titanium nitride layer, and a tungsten layer.

Although not shown, a device isolation layer may be disposed in the first substrate 100 to define active regions. Word lines may be buried in the first substrate 100. The word lines may be electrically disconnected from the first substrate 100 by a gate insulating layer and a capping pattern. Impurity injection regions, which are used as source/drain regions, may be disposed in portions of the first substrate 100, which are placed at both sides of the word lines. Bit lines may be electrically connected to impurity injection regions, respectively, which are formed on a side of the word lines. The conductive contacts 110 may be electrically connected to impurity injection regions, respectively, which are formed on another side of the word lines.

An etch stop layer ES may be disposed on the interlayer insulating layer 120. The etch stop layer ES may be provided to cover the interlayer insulating layer 120 and to expose the conductive contacts 110. The etch stop layer ES may be formed of or include at least one of silicon nitride, silicon boron nitride (SiBN), or silicon carbon nitride (SiCN) and may have a single- or multi-layered structure.

The capacitor CAP may correspond to the capacitor CAP of FIG. 1. The capacitor CAP may include the bottom electrode BE, the dielectric layer DL, and the top electrode TE.

The bottom electrodes BE may be provided to penetrate the etch stop layer ES and to be in contact with the conductive contacts 110, respectively. As shown in FIG. 3, the bottom electrodes BE may have a plug shape having a circular section. The bottom electrodes BE may be arranged in a honeycomb shape, when viewed in a plan view. For example, six bottom electrodes BE may be arranged around one bottom electrode BE to form a hexagonal shape. In some example embodiments, the bottom electrodes BE may have a pillar shape, as shown in FIG. 4. The bottom electrodes BE may be formed of or include at least one of doped polysilicon, metallic materials, metal oxide materials, or metal nitride materials. The bottom electrodes BE may be formed of or include titanium nitride.

A supporting pattern SS may be provided on the first substrate 100. The supporting pattern SS may be provided between adjacent ones of the bottom electrodes BE. In some example embodiments, a plurality of supporting patterns SS may be provided. For example, the supporting pattern SS may include a first supporting pattern SS1 and a second supporting pattern SS2.

Side surfaces of the bottom electrodes BE may be in contact with the first and second supporting patterns SS1 and SS2. The first and second supporting patterns SS1 and SS2 may be spaced apart from each other. The second supporting pattern SS2 may be placed on the first supporting pattern SS1. A top surface of the second supporting pattern SS2 may be located at different heights from top surfaces of the bottom electrodes BE or may be coplanar with the top surfaces of the bottom electrodes BE. The first supporting pattern SS1 and the second supporting pattern SS2 may be formed of or include at least one of silicon nitride (SiN), silicon boron nitride (SiBN), or silicon carbon nitride (SiCN) and may have a single- or multi-layered structure.

The first and second supporting patterns SS1 and SS2 may have different thicknesses (e.g., different thicknesses in the third direction D3 extending perpendicular to an in-plane direction of the first substrate 100) from each other. For example, a thickness of the second supporting pattern SS2 may be thicker than a thickness of the first supporting pattern SS1. The first and second supporting patterns SS1 and SS2 may have (e.g., may be located within) supporting holes SS_h, respectively. The first supporting pattern SS1 may have first supporting holes SS1_h. The second supporting pattern SS2 may have second supporting holes SS2_h. The first and second supporting holes SS1_h and SS2_h may be vertically overlapped with each other. Each of the supporting holes SS_h may be provided to expose side surfaces of three bottom electrodes BE, which are adjacent to each other.

Surfaces of the first supporting pattern SS1, the second supporting pattern SS2, the etch stop layer ES, and the bottom electrodes BE may be conformally covered with the dielectric layer DL. In some example embodiments, the dielectric layer DL may include a silicon oxide layer or a metal oxide layer whose dielectric constant is higher than the silicon oxide layer. In some example embodiments, the dielectric layer DL may be formed of or include at least one of hafnium oxide, aluminum oxide, or zirconium oxide and may have a single- or multi-layered structure.

The top electrode TE may be placed on the dielectric layer DL. The top electrode TE may cover the bottom electrodes BE and the first and second supporting patterns SS1 and SS2. The top electrode TE may be formed of or include at least one of titanium nitride, doped polysilicon, or doped silicon germanium and may have a single- or multi-layered structure.

Referring to FIG. 5A, the dielectric layer DL may include the first to third sub-dielectric layers DL1, DL2, and DL3 and the first and second insertion layers IL1 and IL2. The dielectric layer DL may correspond to the dielectric layer DL of FIG. 1. For example, as shown in FIG. 5A, the first to third sub-dielectric layers DL1, DL2, and DL3 and the first and second insertion layers IL1 and IL2 may be interposed between the bottom electrode BE and the top electrode TE. The first sub-dielectric layer DL1 may cover the bottom electrode BE and the second supporting pattern SS2.

Referring to FIG. 5B, the bottom electrode BE may have a circular shape, when viewed in a plan view. However, in some example embodiments, the bottom electrode BE may be provided to have a seam therein or may be provided have a shape of a hollow doughnut, when viewed in a plan view. In the case where the bottom electrode BE is provided in the shape of the doughnut (e.g., a hollow doughnut), the top electrode TE may further include a portion extended into the bottom electrode BE, and the dielectric layer DL may be interposed between the bottom and top electrodes BE and TE.

The first sub-dielectric layer DL1, the first insertion layer IL1, the second sub-dielectric layer DL2, the second insertion layer IL2, and the third sub-dielectric layer DL3 may be provided to sequentially enclose the bottom electrode BE. For example, the first to third sub-dielectric layers DL1, DL2, and DL3 and the first and second insertion layers IL1 and IL2 may be provided to conformally enclose the bottom electrode BE. The top electrode TE may enclose the third sub-dielectric layer DL3. The first to third sub-dielectric layers DL1, DL2, and DL3 and the first and second insertion layers IL1 and IL2 may be provided to have substantially the same or similar features as described with reference to FIG. 1.

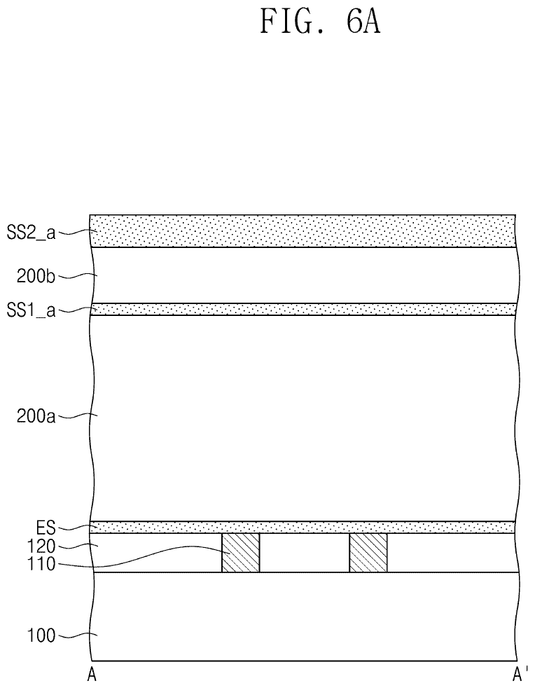

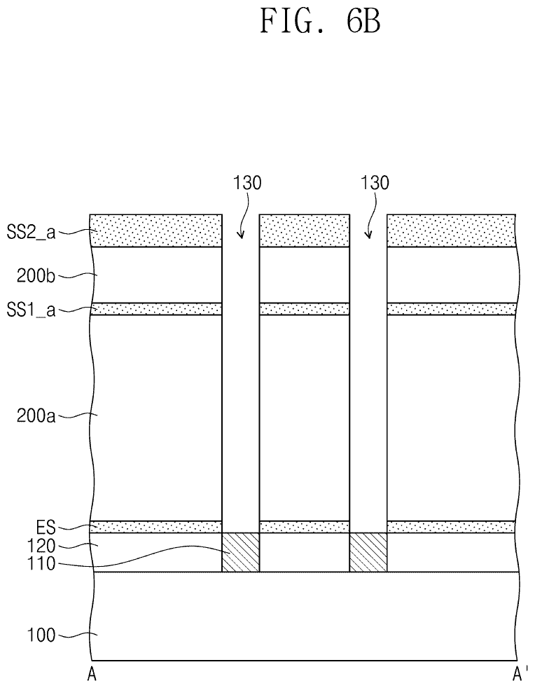

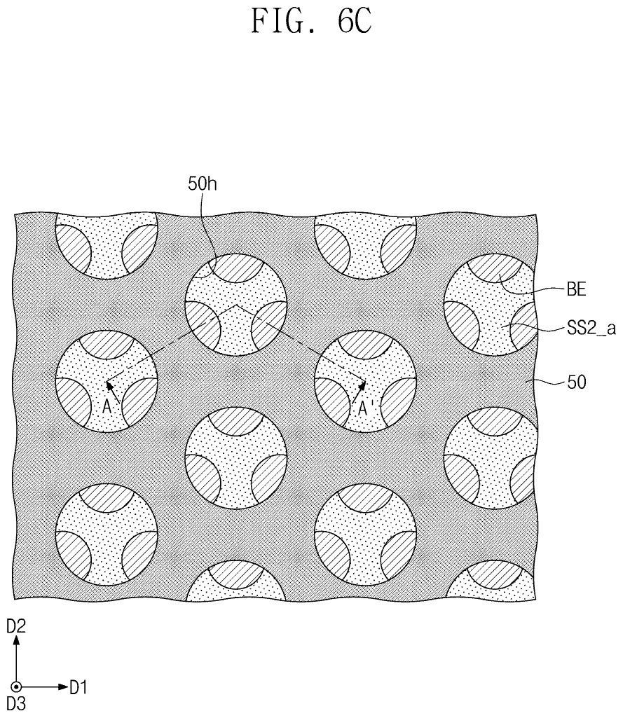

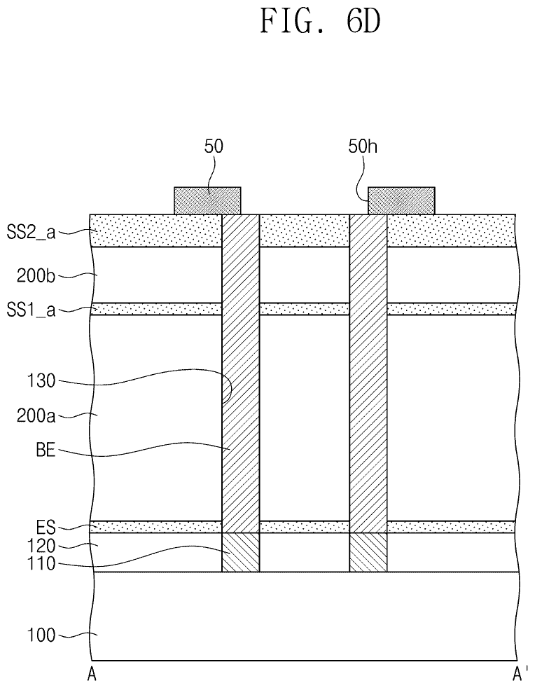

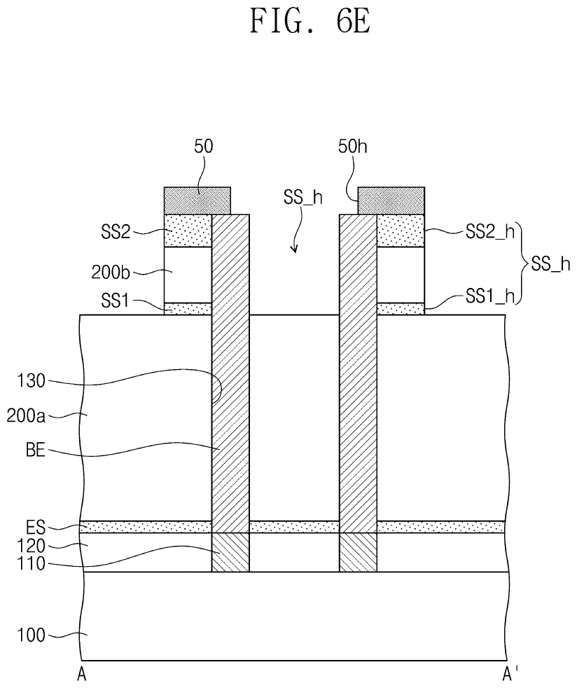

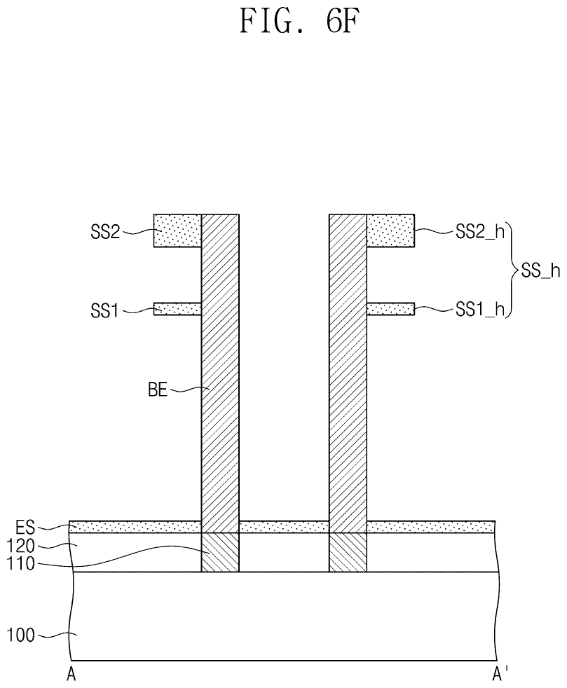

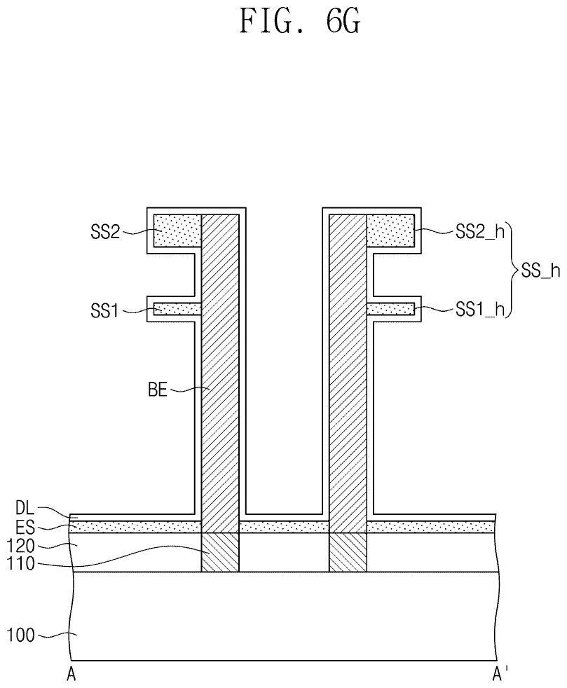

FIGS. 6A, 6B, 6D, 6E, 6F, and 6G are sectional views sequentially illustrating a method of fabricating a semiconductor device, which has the section of FIG. 4, according to some example embodiments of the inventive concepts. FIG. 6C is a plan view illustrating a method of fabricating a semiconductor device, which has the plan view of FIG. 3, according to some example embodiments of the inventive concepts. FIG. 6D corresponds to a section taken along a line A-A′ of FIG. 6C.

Referring to FIG. 6A, the interlayer insulating layer 120 may be formed on the first substrate 100. The conductive contacts 110 may be formed in the interlayer insulating layer 120. The etch stop layer ES may be formed on the interlayer insulating layer 120 and the conductive contacts 110. A first mold layer 200a, a first supporting layer SS1_a, a second mold layer 200b, and a second supporting layer SS2_a may be sequentially stacked on the etch stop layer ES.

The first and second supporting layers SS1_a and SS2_a may be formed of or include the same material. The first and second mold layers 200a and 200b may be formed of or include the same material and may be formed of or include a material having an etch selectivity with respect to the first and second supporting layers SS1_a and SS2_a. For example, the first and second mold layers 200a and 200b may be formed of or include silicon oxide. The first and second supporting layers SS1_a and SS2_a may be formed of or include at least one of silicon nitride (SiN), silicon boron nitride (SiBN), or silicon carbon nitride (SiCN) and may have a single- or multi-layered structure. The first mold layer 200a may be formed to be thicker than the second mold layer 200b. The second supporting layer SS2_a may be formed to be thicker than the first supporting layer SS1_a.

Referring to FIG. 6B, the second supporting layer SS2_a, the second mold layer 200b, the first supporting layer SS1_a, the first mold layer 200a, and the etch stop layer ES may be sequentially etched to form bottom electrode holes 130 exposing the conductive contacts 110, respectively.

Referring to FIGS. 6C and 6D, a conductive layer may be formed on the first substrate 100 to fill the bottom electrode holes 130, and an etch-back process may be performed on the conductive layer to form the bottom electrodes BE in the bottom electrode holes 130, respectively. Thereafter, a top surface of the second supporting layer SS2_a may be exposed. A mask pattern 50 may be formed on the second supporting layer SS2_a. The mask pattern 50 may include openings 50h, which are formed to partially expose the top surfaces of the bottom electrodes BE. In some example embodiments, each of the openings 50h may be formed to partially expose the top surfaces of three adjacent ones of the bottom electrodes BE and the top surface of the second supporting layer SS2_a therebetween.

Referring to FIG. 6E, the second supporting layer SS2_a exposed by the openings 50h, the second mold layer 200b thereunder, and the first supporting layer SS1_a thereunder may be sequentially patterned by an anisotropic etching process using the mask pattern 50 as an etch mask, and as a result, the supporting holes SS_h exposing a top surface of the first mold layer 200a may be formed. Here, the first supporting layer SS1_a may be etched to form the first supporting pattern SS1 with the first supporting holes SS1_h. Similarly, the second supporting layer SS2_a may be etched to form the second supporting pattern SS2 with the second supporting holes SS2_h. The first supporting holes SS1_h may be vertically overlapped with the second supporting holes SS2_h, respectively, and may have the same or similar shape and size as the second supporting holes SS2_h. In some example embodiments, a side surface of the second mold layer 200b may be exposed during this step.

Referring to FIG. 6F, an isotropic etching process may be performed to remove the first and second mold layers 200a and 200b, which are exposed by the supporting holes SS_h, and as a result, surfaces of the bottom electrodes BE may be exposed. Here, a top surface of the etch stop layer ES and top, side, and bottom surfaces of the first and second supporting patterns SS1 and SS2 may be exposed to the outside.

In some example embodiments, the second supporting pattern SS2 with the second supporting hole SS2_h may be formed after anisotropically etching the second supporting layer SS2_a, and then, an isotropic etching process may be performed to remove the second mold layer 200b through the second supporting hole SS2_h. Thereafter, an anisotropic etching process etching the first supporting layer SS1_a may be performed to form the first supporting pattern SS1 with the first supporting hole SS1_h, and an isotropic etching process may be performed to remove the first mold layer 200a through the first supporting hole SS1_h.

Referring to FIGS. 5A, 5B, and 6G, an atomic layer deposition (ALD) process may be performed to deposit the dielectric layer DL on the bottom electrodes BE, the etch stop layer ES, and the first and second supporting patterns SS1 and SS2. In some example embodiments, the dielectric layer DL may be formed by the same process as described with reference to FIGS. 1 and 2. Thereafter, the semiconductor device having the section of FIG. 4 may be fabricated by forming the top electrode TE on the dielectric layer DL.

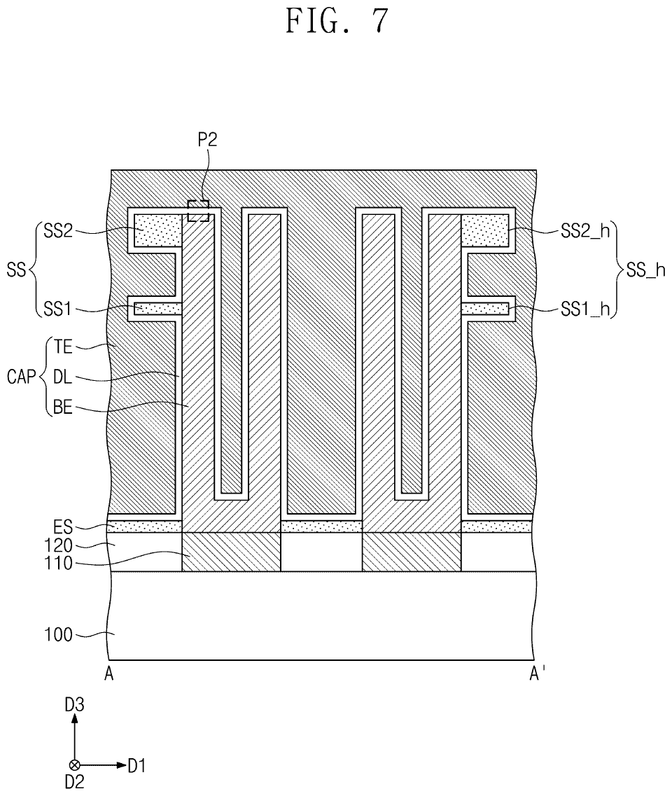

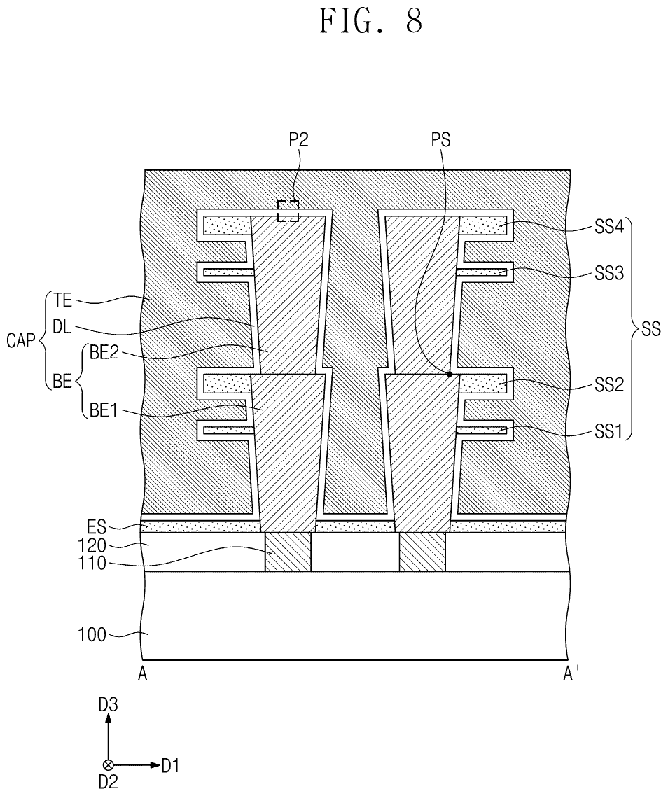

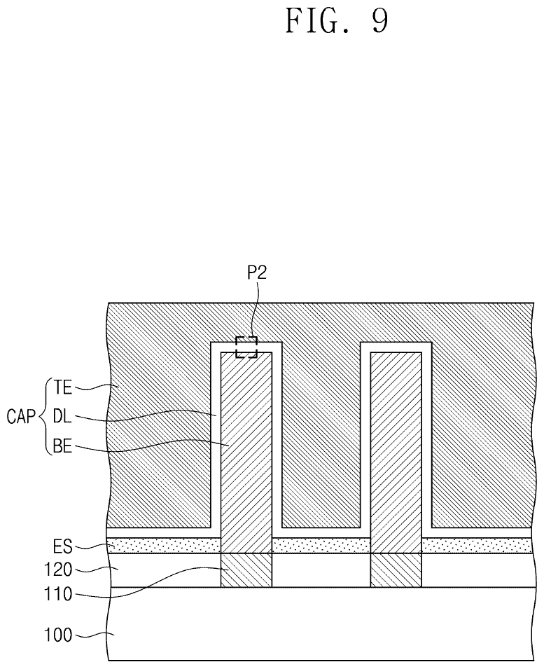

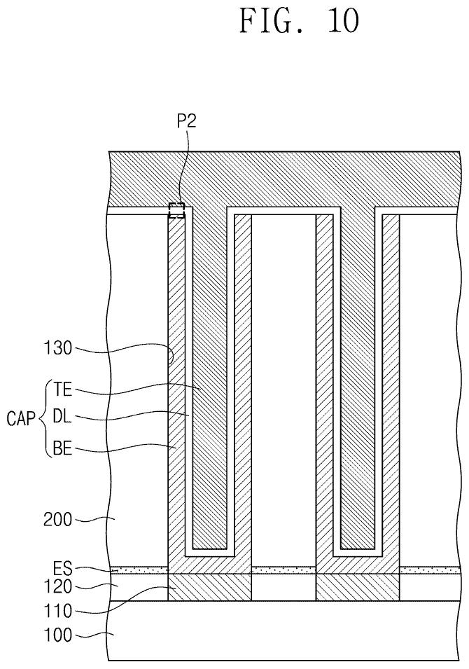

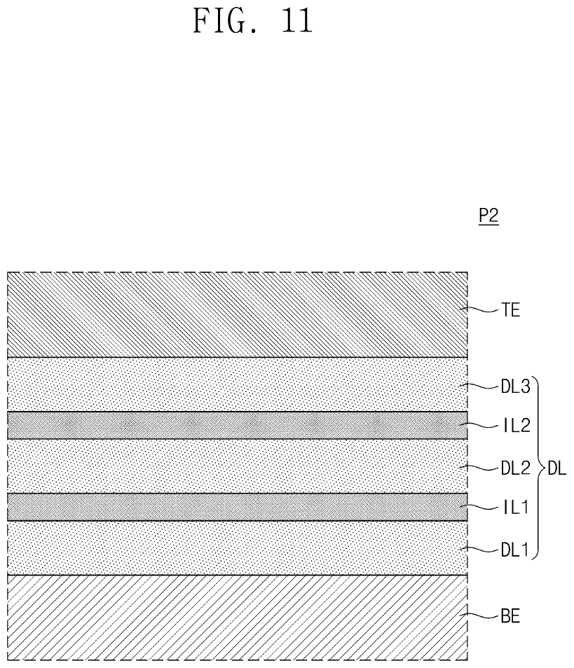

FIG. 7 is a sectional view taken along the line A-A′ of FIG. 3 according to some example embodiments of the inventive concepts. FIG. 8 is a sectional view taken along the line A-A′ of FIG. 3 according to some example embodiments of the inventive concepts. FIG. 9 is a sectional view illustrating a semiconductor device according to some example embodiments of the inventive concepts. FIG. 10 is a sectional view illustrating a semiconductor device according to some example embodiments of the inventive concepts. FIG. 11 is an enlarged sectional view illustrating a portion ‘P2’ of FIGS. 7, 8, 9, and 10.

Referring to FIGS. 7 and 11, each of the bottom electrodes BE in the semiconductor device according to some example embodiments may have a hollow cup shape or a cylinder shape. Each of the bottom electrodes BE may have an inner side surface and an outer side surface. The first and second supporting patterns SS1 and SS2 may be disposed on the outer side surface of the bottom electrodes BE. The dielectric layer DL may be extended to cover the inner side surface of each of the bottom electrodes BE. The top electrode TE may be extended to face the inner side surface of the bottom electrodes BE. Except for the afore-described features, the semiconductor device according to some example embodiments, including the example embodiments shown in FIG. 7, may have substantially the same or similar features as that described with reference to FIGS. 1 to 5B.

Referring to FIGS. 8 and 11, each of the bottom electrodes BE may include a lower pillar BE1 and an upper pillar BE2 thereon. There may be an interface between the lower and upper pillars BE1 and BE2 or there may not be (e.g., the lower and upper pillars BE1 and BE2 may be separate portions of a single, unitary piece of material). Each of side surfaces of the lower and upper pillars BE1 and BE2 may be inclined at an angle. Each of side surfaces of the bottom electrodes BE may have an inflection point PS between the lower and upper pillars BE1 and BE2. An upper portion of the lower pillar BE1 may be wider than a lower portion of the upper pillar BE2.

The supporting pattern SS may include a first supporting pattern SS1, a second supporting pattern SS2, a third supporting pattern SS3, and a fourth supporting pattern SS4. Side surfaces of the lower pillar BE1 may be in contact with the first and second supporting patterns SS1 and SS2, which are spaced apart from each other. Side surfaces of the upper pillar BE2 may be in contact with the third and fourth supporting patterns SS3 and SS4, which are spaced apart from each other. The dielectric layer DL may be extended to cover the first to fourth supporting patterns SS1 to SS4. Except for the afore-described features, the semiconductor device according to some example embodiments, including the example embodiments shown in FIG. 8, may have substantially the same or similar features as that described with reference to FIGS. 1 to 5B.

Referring to FIGS. 9 and 11, the conductive contacts 110 and the interlayer insulating layer 120 may be disposed on the first substrate 100. The etch stop layer ES may be disposed on the interlayer insulating layer 120. The bottom electrodes BE may be provided to penetrate the etch stop layer ES and to be in contact with the conductive contacts 110, respectively. In some example embodiments, the supporting patterns SS1 and SS2 of FIG. 3 may not be provided (e.g., may be absent, omitted, etc.). In this case, the etch stop layer ES may be used to support the bottom electrodes BE. The dielectric layer DL may be formed on all of the side surfaces of the bottom electrodes BE. Except for the afore-described features, the semiconductor device according to some example embodiments, including the example embodiments shown in FIG. 9, may have substantially the same or similar features as that described with reference to FIGS. 1 to 5B.

Referring to FIGS. 10 and 11, the conductive contacts 110 and the interlayer insulating layer 120 may be disposed on the first substrate 100. The etch stop layer ES may be disposed on the interlayer insulating layer 120. A mold layer 200 may be disposed on the etch stop layer ES. The mold layer 200 may be provided to define the bottom electrode holes 130 exposing the conductive contacts 110. The bottom electrodes BE may be disposed in the bottom electrode holes 130, respectively.

The bottom electrodes BE may have a hollow cup shape or a cylinder shape. Each of the bottom electrodes BE may have an inner side surface and an outer side surface. The outer side surfaces of the bottom electrodes BE may be in contact with the mold layer 200. Top surfaces of the bottom electrodes BE may be coplanar with a top surface of the mold layer 200. The dielectric layer DL may be provided to cover the inner side surface of each of the bottom electrodes BE and the top surface of the mold layer 200. The dielectric layer DL may not cover the outer side surfaces of the bottom electrodes BE.

The top electrode TE may be extended to face the inner side surface of each of the bottom electrodes BE. In some example embodiments, the supporting patterns SS1 and SS2 of FIG. 3 may not be provided. In this case, the mold layer 200 may be used to support the bottom electrodes BE. Except for the afore-described features, the semiconductor device according to some example embodiments, including the example embodiments shown in FIG. 10, may have substantially the same or similar features as that described with reference to FIGS. 1 to 5B.

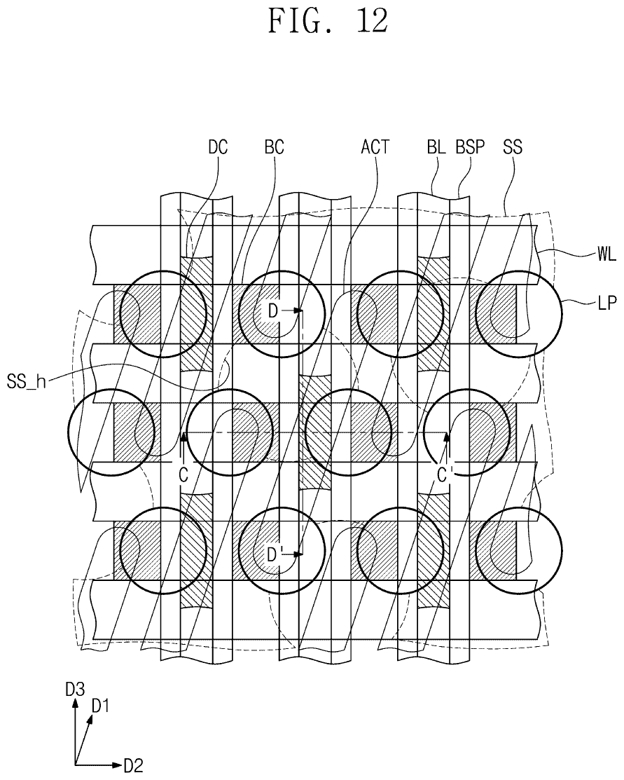

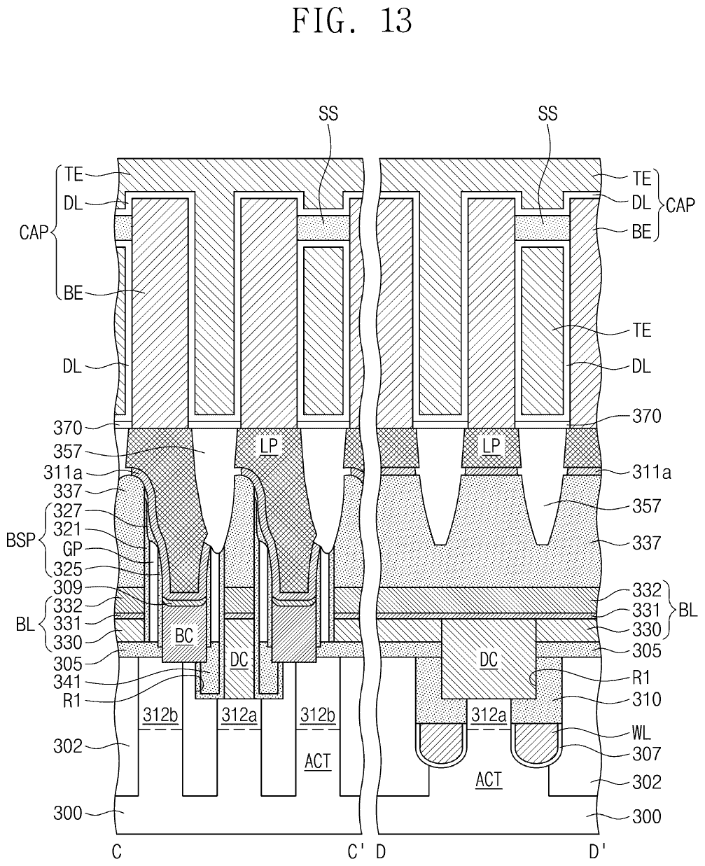

FIG. 12 is a plan view illustrating a semiconductor device according to some example embodiments of the inventive concepts. FIG. 13 is a sectional view taken along lines C-C′ and D-D′ of FIG. 12 according to some example embodiments of the inventive concepts.

Referring to FIGS. 12 and 13, device isolation patterns 302 may be disposed in a second substrate 300 to define active portions ACT. Each of the active portions ACT may have an isolated shape. When viewed in a plan view, each of the active portions ACT may be a bar-shaped pattern elongated in a first direction D1. When viewed in a plan view, the active portions ACT may correspond to portions of the second substrate 300, respectively, which are enclosed by the device isolation patterns 302. The second substrate 300 may include a semiconductor material. The active portions ACT may be arranged to be parallel to the first direction D1 and parallel to each other, and an end portion of each of the active portions ACT may be placed to be adjacent to a center of another active portion ACT adjacent thereto.

Word lines WL may be disposed to cross the active portions ACT. The word lines WL may be disposed in grooves, which are formed in the device isolation patterns 302 and the active portions ACT. The word lines WL may be parallel to a second direction D2, which is not parallel to the first direction D1. The word lines WL may be formed of a conductive material. A gate dielectric layer 307 may be disposed between each of the word lines WL and an inner surface of each of the grooves. Although not shown, the groove may be formed to have a relatively large depth in the device isolation patterns 302 and a relatively small depth in the active portions ACT. The gate dielectric layer 307 may be formed of or include at least one of thermal oxide, silicon nitride, silicon oxynitride, or high-k dielectric materials. Each of the word lines WL may have an uneven bottom surface.

A first doped region 312a may be disposed in each of the active portions ACT between a pair of the word lines WL, and a pair of second doped regions 312b may be respectively disposed in opposite edge regions of each of the active portions ACT. In some example embodiments, the first and second doped regions 312a and 312b may be doped with n-type impurities. The first doped region 312a may correspond to a common drain region, and the second doped regions 312b may correspond to source regions. Each word line WL and the first and second doped regions 312a and 312b adjacent thereto may constitute a transistor. Since the word lines WL are disposed in the grooves, a channel region below the word line WL may have an increased channel length within a given planar area. Thus, it may be possible to suppress the short channel effect or the like.

Top surfaces of the word lines WL may be lower than top surfaces of the active portions ACT. A word line capping pattern 310 may be disposed on each of the word lines WL. The word line capping pattern 310 may be a line-shaped pattern, which is extended in a length direction of the word line WL, and may cover the entire top surface of the word line WL. The word line capping patterns 310 may fill the grooves on the word lines WL. The word line capping pattern 310 may be formed of or include, for example, silicon nitride.

An interlayer insulating pattern 305 may be disposed on the second substrate 300. The interlayer insulating pattern 305 may be formed of or include at least one of silicon oxide, silicon nitride, or silicon oxynitride and may have a single- or multi-layered structure. The interlayer insulating patterns 305 may be island-shaped patterns, which are spaced apart from each other, when viewed in a plan view. The interlayer insulating pattern 305 may be formed to cover both of end portions of two active portions ACT, which are adjacent to each other.

Upper portions of the second substrate 300, the device isolation pattern 302, and the word line capping pattern 310 may be partially recessed to form a first recess region R1. The first recess region R1 may be provided to form a mesh or net shape, when viewed in a plan view. A side surface of the first recess region R1 may be aligned to a side surface of the interlayer insulating pattern 305.

Bit lines BL may be disposed on the interlayer insulating pattern 305. The bit lines BL may be disposed to cross the word line capping patterns 310 and the word lines WL. As shown in FIG. 12, the bit lines BL may be parallel to a third direction D3, which is not parallel to both of the first and second directions D1 and D2. The bit lines BL may include a bit line polysilicon pattern 330, a bit line ohmic pattern 331, and a bit line metal-containing pattern 332, which are sequentially stacked. The bit line polysilicon pattern 330 may be formed of or include at least one of doped or undoped polysilicon. The bit line ohmic pattern 331 may include a metal silicide layer. The bit line metal-containing pattern 332 may be formed of or include at least one of metallic materials (e.g., tungsten, titanium, and tantalum) or conductive metal nitride materials (e.g., titanium nitride, tantalum nitride, and tungsten nitride). Bit line capping patterns 337 may be disposed on the bit lines BL, respectively. The bit line capping patterns 337 may be formed of or include an insulating material (e.g., silicon nitride).

Bit line contacts DC may be disposed in the first recess region R1, which is formed to cross the bit lines BL. The bit line contacts DC may be formed of or include doped or undoped polysilicon. When viewed in the sectional view taken along a line D-D′ of FIG. 13, a side surface of the bit line contact DC may be in contact with the side surface of the interlayer insulating pattern 305. When viewed in the plan view of FIG. 12, a side surface of the bit line contact DC, which is in contact with the interlayer insulating pattern 305, may be concave. The bit line contact DC may electrically connect the first doped region 312a to the bit line BL.

A lower gapfill insulating pattern 341 may be formed in a portion of the first recess region R1 where is not filled with the bit line contact DC. The lower gapfill insulating pattern 341 may be formed of or include at least one of silicon oxide, silicon nitride, or silicon oxynitride and may have a single- or multi-layered structure.

Storage node contacts BC may be disposed between a pair of the bit lines BL, which are adjacent to each other. The storage node contacts BC may be spaced apart from each other. The storage node contacts BC may be formed of or include doped or undoped polysilicon. The storage node contacts BC may have concave top surfaces. An insulating pattern (not shown) may be provided between the bit lines BL and between the storage node contacts BC.

A bit line spacer BSP may be interposed between the bit line BL and the storage node contact BC. The bit line spacer BSP may include a first sub-spacer 321 and a second sub-spacer 325, which are spaced apart from each other by a gap region GP. The gap region GP may be referred to as an air gap region. The first sub-spacer 321 may cover a side surface of the bit line BL and a side surface of the bit line capping pattern 337. The second sub-spacer 325 may be adjacent to the storage node contact BC. The first and second sub-spacers 321 and 325 may be formed of or include the same material. For example, the first and second sub-spacers 321 and 325 may be formed of or include silicon nitride.

A bottom surface of the second sub-spacer 325 may be lower than a bottom surface of the first sub-spacer 321. A height of an upper end of the second sub-spacer 325 may be lower than a height of an upper end of the first sub-spacer 321. This may make it possible to increase a process margin in a subsequent process of forming a landing pad LP. Accordingly, it may be possible to prevent the landing pad LP from being disconnected from the storage node contact BC. The first sub-spacer 321 may be extended to cover a side surface of the bit line contact DC and side and bottom surfaces of the first recess region R1. That is, the first sub-spacer 321 may be interposed between the bit line contact DC and the lower gapfill insulating pattern 341, between the word line capping pattern 310 and the lower gapfill insulating pattern 341, between the second substrate 300 and the lower gapfill insulating pattern 341, and between the device isolation pattern 302 and the lower gapfill insulating pattern 341.

A storage node ohmic layer 309 may be disposed on the storage node contact BC. The storage node ohmic layer 309 may be formed of or include at least one of metal silicide materials. The storage node ohmic layer 309, the first and second sub-spacers 321 and 325, and the bit line capping pattern 337 may be covered with a diffusion prevention pattern 311a with a uniform thickness. The diffusion prevention pattern 311a may include at least one of metal nitride materials (e.g., titanium nitride and tantalum nitride). The landing pad LP may be disposed on the diffusion prevention pattern 311a. The landing pads LP may correspond to the conductive contact 110 of FIG. 4. The landing pad LP may be formed of or include a metal-containing material (e.g., tungsten). An upper portion of the landing pad LP may cover a top surface of the bit line capping pattern 337 and may have a larger width than the storage node contact BC. A center of the landing pad LP may be shifted from a center of the storage node contact BC in the second direction D2. A portion of the bit line BL may be vertically overlapped with the landing pad LP. An upper side surface of the bit line capping pattern 337 may be overlapped with the landing pad LP and may be covered with a third sub-spacer 327. A pad separation pattern 357 may be interposed between the landing pads LP. The pad separation pattern 357 may correspond to the interlayer insulating layer 120 of FIG. 4. The pad separation pattern 357 may include a silicon nitride layer, a silicon oxide layer, a silicon oxynitride layer, or a porous layer. The pad separation pattern 357 may define an upper end of the gap region GP.

The bottom electrodes BE may be disposed on the landing pads LP, respectively. Side surfaces of the bottom electrodes BE may be connected to the supporting pattern SS. The supporting pattern SS may include a plurality of supporting holes SS_h.

Between the bottom electrodes BE, top surfaces of the pad separation pattern 357 and the landing pads LP may be covered with an etch stop layer 370. The etch stop layer 370 may be formed of or include at least one of insulating materials (e.g., silicon nitride, silicon oxide, and silicon oxynitride). The bottom electrodes BE and the supporting pattern SS may be covered with the dielectric layer DL. The dielectric layer DL may be covered with the top electrode TE. The bottom electrode BE, the dielectric layer DL, and the top electrode TE may constitute the capacitor CAP. The capacitor CAP may correspond to the capacitor CAP of FIG. 1.

In the semiconductor device according to some example embodiments of the inventive concepts, the gap region GP may be interposed between the first and second sub-spacers 321 and 325, and since the air/gas/vacuum has a lower dielectric constant than silicon oxide, a parasitic capacitance between the bit line BL and the storage node contact BC may be reduced. Except for the afore-described features, the semiconductor device according to some example embodiments may have substantially the same or similar features as that described with reference to FIGS. 1 to 5B.

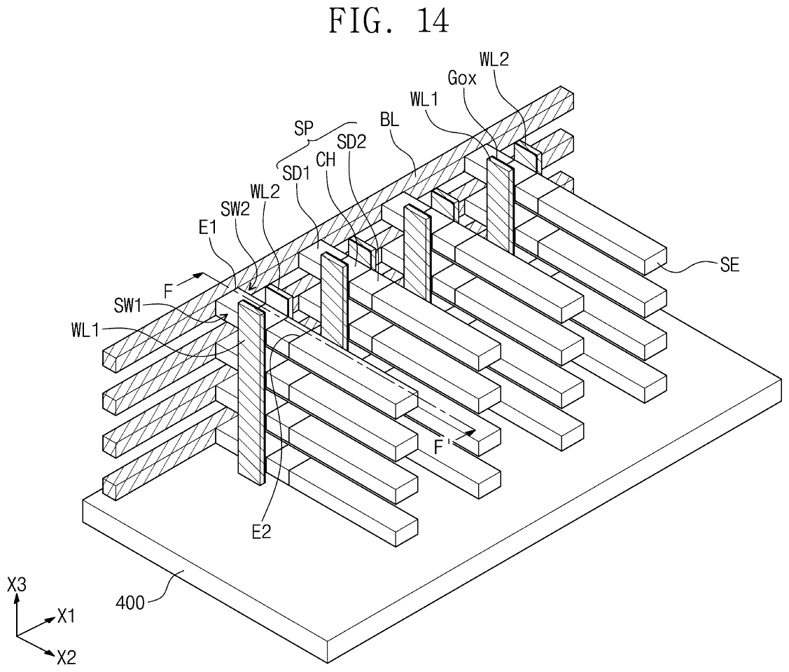

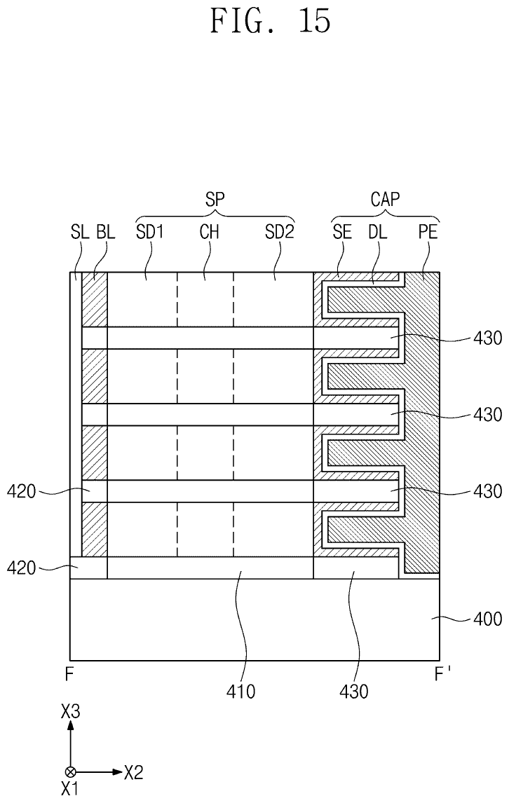

FIG. 14 is a perspective view illustrating a three-dimensional semiconductor memory device according to some example embodiments of the inventive concepts. FIG. 15 is a sectional view taken along a line F-F′ of FIG. 14.

Referring to FIGS. 14 and 15, semiconductor patterns SP may be disposed on a fourth substrate 400 to be spaced apart from each other in a first direction X1 and a third direction X3 crossing each other. Each of the semiconductor patterns SP may have an elongated bar shape, which is extended in a second direction X2 that is not parallel to both of the first and third directions X1 and X3. The first and second directions X1 and X2 may be parallel to a top surface of a fourth substrate 400. The third direction X3 may be perpendicular to the top surface of the fourth substrate 400. Each of the semiconductor patterns SP may have a first end portion E1 and a second end portion E2, which are spaced apart from each other. In addition, each of the semiconductor patterns SP may have a first side surface SW1 and a second side surface SW2, which are spaced apart from each other and connect the first end portion E1 to the second end portion E2. The semiconductor patterns SP may be formed of or include at least one of silicon or germanium. Each of the semiconductor patterns SP may include a first source/drain region SD1 adjacent to the first end portion E1, a second source/drain region SD2 adjacent to the second end portion E2, and a channel region CH interposed between the first and second source/drain regions SD1 and SD2. Each of the first and second source/drain regions SD1 and SD2 may be an impurity-doped region, which is formed in the semiconductor pattern SP. The channel region CH may be doped with impurities. For example, the first and second source/drain regions SD1 and SD2 may be doped with impurities of a first conductivity type, and the channel region CH may be doped with impurities of a second conductivity type that is different from the first conductivity type.

The bit lines BL may be stacked on the fourth substrate 400 to be spaced apart from each other in the third direction X3. The bit lines BL may be extended in the first direction X1. The first end portions E1 of the semiconductor patterns SP, which are located at the same height, may be connected to one of the bit lines BL.

A first electrode SE may be connected to the second end portions E2 of the semiconductor patterns SP. The first electrode SE may correspond to the bottom electrode BE of FIG. 1. The first electrode SE may have a hollow cup or cylinder shape that is extended in a horizontal direction or is rotated by the right angle.

First word lines WL1 may be adjacent to the first side surfaces SW1 of the semiconductor patterns SP. Second word lines WL2 may be adjacent to the second side surfaces SW2 of the semiconductor patterns SP. The first and second word lines WL1 and WL2 may be extended from the top surface of the fourth substrate 400 in the third direction D3. The first word line WL1 may be spaced apart from the second word line WL2, with the channel region CH of the semiconductor pattern SP interposed therebetween. A gate insulating layer Gox may be interposed between the first and second word lines WL1 and WL2 and the semiconductor patterns SP. The gate insulating layer Gox may be a single- or multi-layered structure and may be formed of or include at least one of high-k dielectric materials, silicon oxide, silicon nitride, or silicon oxynitride. As an example, the high-k dielectric materials may include hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

Each of the bit lines BL and the first and second word lines WL1 and WL2 may be formed of or include at least one of conductive materials. In some example embodiments, the conductive material may be formed of or include at least one of doped semiconductor materials (e.g., doped silicon and doped germanium), conductive metal nitride materials (e.g., titanium nitride and tantalum nitride), metallic materials (e.g., tungsten, titanium, and tantalum), or metal-semiconductor compounds (e.g., tungsten silicide, cobalt silicide, and titanium silicide).

The bit lines BL may be extended in the first direction X1. The bit lines BL may be in contact with a separation insulating pattern SL. When viewed in a plan view, the separation insulating pattern SL may be a line-shaped pattern that is extended in the first direction D1.

The first word lines WL1 may serve as gate electrodes actually controlling charge conduction through the channel regions CH. The second word lines WL2 may serve as back gate electrodes auxiliary controlling the conduction of electric charges in the channel regions CH. A first interlayer insulating layer 410 may be interposed between the semiconductor patterns SP. A second interlayer insulating layer 420 may be interposed between the bit lines BL. A third interlayer insulating layer 430 may be interposed between the first electrodes SE. The third interlayer insulating layer 430 may be used to support the first electrodes SE. The separation insulating pattern SL may be in contact with side surfaces of the bit lines BL and the second interlayer insulating layers 420. The first to third interlayer insulating layers 410, 420, and 430 and the separation insulating pattern SL may be formed of or include at least one of silicon oxide, silicon oxynitride, or silicon nitride and may have a single- or multi-layered structure.

The first electrode SE may be in contact with the third interlayer insulating layer 430. The first electrodes SE may be in contact with the dielectric layer DL. The dielectric layer DL may be in contact with a second electrode PE. The first electrode SE, the dielectric layer DL, and the second electrode PE may constitute the capacitor CAP. The capacitor CAP may correspond to the capacitor CAP of FIG. 1. Except for the afore-described features, the semiconductor device according to some example embodiments, including the example embodiments shown in FIGS. 14 and 15, may have substantially the same or similar features as that described with reference to FIGS. 1 to 5B.

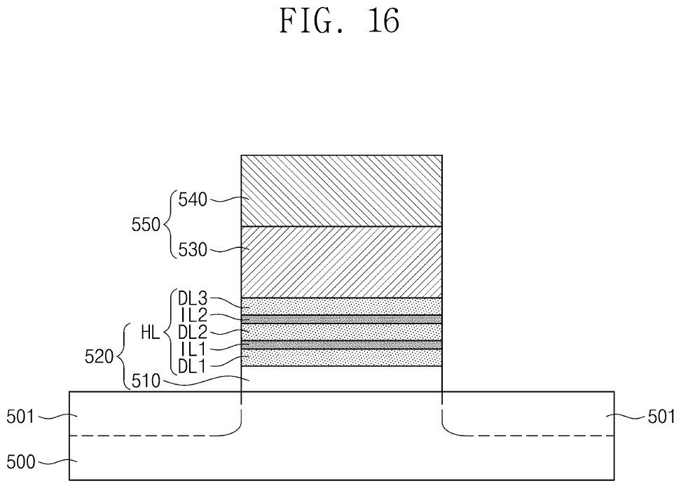

FIG. 16 is a sectional view illustrating a semiconductor device according to some example embodiments of the inventive concepts.

Referring to FIG. 16, a gate insulating layer 520 and a gate electrode 550 may be sequentially stacked on a substrate 500. The gate insulating layer 520 may include a silicon oxide layer 510 and a high-k dielectric layer HL, which are sequentially stacked. The high-k dielectric layer HL may have substantially the same structure as the dielectric layer DL described with reference to FIG. 1. The gate electrode 550 may include a first conductive pattern 530 and a second conductive pattern 540, which are sequentially stacked. The first conductive pattern 530 may be a p-type metal pattern or an n-type metal pattern. The n-type metal pattern may be formed of or include at least one of lanthanum (La), lanthanum oxide (LaO), tantalum (Ta), tantalum nitride (TaN), niobium (Nb), or titanium nitride (TiN). The p-type metal pattern may be formed of or include at least one of aluminum (Al), aluminum oxide, titanium nitride (TiN), tungsten nitride (WN), or ruthenium oxide (RuO₂). The second conductive pattern 540 may be formed of or include tungsten. Source/drain regions 501 may be disposed in the substrate 500 and at both sides (e.g., opposite sides) of the gate electrode 550.

In a semiconductor device according to some example embodiments of the inventive concepts, insertion layers may include a material, which is inserted in a dielectric layer and is chosen from hafnium oxide, zirconium oxide, and hafnium-zirconium oxide, and a material having a large band gap. By providing the multiple insertion layers in the dielectric layer, it may be possible to prevent a dielectric constant of the dielectric layer from being lowered, or reduce or minimize such lowering of the dielectric constant of the dielectric layer, and reduce, minimize, or prevent a leakage current passing through the dielectric layer. As a result, based on the semiconductor device including a dielectric layer that includes sub-dielectric layers and insertion layers according to some example embodiments, the semiconductor device may exhibit reduced, minimized, or prevented leakage current passing through the dielectric layer and thus may exhibit improved performance (e.g., improved capacitance, reduced signal loss due to leakage current, reduced power consumption due to leakage current, etc.), improved reliability (e.g., reduced risk of device failure due to leakage current through the dielectric layer and/or reduced risk of compromising the dielectric constant of the insertion layers due to crystallinity degradation based on the insertion layers being formed in the dielectric layer DL through a deposition process), or the like.

While example embodiments of the inventive concepts have been particularly shown and described, it will be understood by one of ordinary skill in the art that variations in form and detail may be made therein without departing from the spirit and scope of the attached claims.

What is claimed is:

1. A semiconductor device, comprising:
a capacitor, the capacitor including,
a bottom electrode,
a first dielectric layer on the bottom electrode,
a first insertion layer on the first dielectric layer,
a second dielectric layer on the first insertion layer,
a second insertion layer on the second dielectric layer,
a third dielectric layer on the second insertion layer, and
a top electrode on the third dielectric layer,
wherein at least one of the first to third dielectric layers includes a first element, and
wherein at least one of the first insertion layer or the second insertion layer comprises both the first element and a second element, the second element different from the first element.

2. The semiconductor device of claim 1, wherein each of the first to third dielectric layers comprises one of hafnium oxide, zirconium oxide, or hafnium-zirconium oxide.

3. The semiconductor device of claim 1, wherein the first element comprises one of Zr, Hf, Si, Ti, Nb, Ba, Mg, Lu, Ta, Ca, Ga, Y, Al, La, Ge, Sr, or Gd.

4. The semiconductor device of claim 1, wherein the second element comprises one of Al, Zr, Hf, Si, Ba, Mg, Ca, Ga, Y, La, B, Be, Ge, Sr, or Gd.

5. The semiconductor device of claim 4, wherein each of the first and second insertion layers comprise one of zirconium oxide (ZrₓO₂) doped with aluminum (Al), hafnium oxide (HfO₂) doped with aluminum (Al), Al_{y}ZrₓO₂, or Al_{y}HfₓO₂ (0<x≤1 and 0<y≤1).

6. The semiconductor device of claim 1, wherein each of the first to third dielectric layers has a thickness ranging from 1 Å to 60 Å.

7. The semiconductor device of claim 1, wherein each of the first and second insertion layers has a thickness ranging from 0.3 Å to 10 Å.

8. The semiconductor device of claim 1, wherein each of the first and second insertion layers has at least one of tetragonal crystal structure or orthorhombic crystal structure.

9. The semiconductor device of claim 1, wherein
the first to third dielectric layers are spaced apart from each other, and
the first and second insertion layers are spaced apart from each other.

10. A semiconductor device, comprising:
a substrate;
word lines in the substrate;
a first impurity region in the substrate at a side of the word lines;
a second impurity region in the substrate and between the word lines;
a bit line connected to the second impurity region, the bit line on the substrate such that the bit line crosses the word lines;
a conductive contact connected to the first impurity region, the conductive contact on the substrate;
a bottom electrode on the conductive contact;
a dielectric layer on the bottom electrode;
a top electrode on the dielectric layer; and
a supporting pattern in contact with an upper side surface of the bottom electrode,
wherein the dielectric layer includes
first to third sub-dielectric layers, the first to third sub-dielectric layers sequentially stacked, and
first and second insertion layers between separate, respective sets of adjacent sub-dielectric layers of the first to third sub-dielectric layers,
wherein at least one of the first to third sub-dielectric layers includes a first element,
wherein at least one of the first insertion layer or the second insertion layer includes the first element, and
wherein each of the first and second insertion layers has a thickness ranging from 0.3 Å to 10 Å.

11. The semiconductor device of claim 10, wherein a thickness of the dielectric layer ranges from 10 Å to 100 Å.

12. The semiconductor device of claim 10, wherein each of the first to third sub-dielectric layers has a thickness ranging from 1 Å to 60 Å.

13. The semiconductor device of claim 10, wherein each of the first to third sub-dielectric layers comprises at least one of hafnium oxide, zirconium oxide, or hafnium-zirconium oxide.

14. The semiconductor device of claim 10, wherein at least one of the first insertion layer or the second insertion layer further comprises a second element, the second element different from the first element.

15. The semiconductor device of claim 14, wherein each of the first and second insertion layers comprises one of zirconium oxide (ZrₓO₂) doped with aluminum (Al), hafnium oxide (HfₓO₂) doped with aluminum (Al), Al_{y}ZrₓO₂, or Al_{y}HfₓO₂ (0<x≤1 and 0<y≤1).

16. The semiconductor device of claim 14, wherein
the first element comprises one of Zr, Hf, Si, Ti, Nb, Ba, Mg, Lu, Ta, Ca, Ga, Y, Al, La, Ge, Sr, or Gd, and
the second element comprises one of Al, Zr, Hf, Si, Ba, Mg, Ca, Ga, Y, La, B, Be, Ge, Sr, or Gd.

17. The semiconductor device of claim 10, wherein each of the first and second insertion layers has at least one of tetragonal crystal structure or orthorhombic crystal structure.

18. A semiconductor device, comprising:
a substrate;
conductive contacts on the substrate; and
capacitors on the conductive contacts,
wherein each of the capacitors includes
a bottom electrode,
a dielectric layer on the bottom electrode, and
a top electrode on the dielectric layer,
wherein the dielectric layer includes
first to third sub-dielectric layers, the first to third sub-dielectric layers sequentially stacked; and
first and second insertion layers between separate, respective sets of adjacent sub-dielectric layers of the first to third sub-dielectric layers,
wherein each of the first and second insertion layers has at least one of tetragonal crystal structure or orthorhombic crystal structure.

19. The semiconductor device of claim 18, wherein
each of the first to third sub-dielectric layers comprises at least one of hafnium oxide, zirconium oxide, or hafnium-zirconium oxide,
at least one of the first to third sub-dielectric layers comprises a first element, and
at least one of the first insertion layer or the second insertion layer comprises both the first element and a second element, the second element different from the first element.

20. The semiconductor device of claim 19, wherein each of the first and second insertion layers comprises one of zirconium oxide (ZrₓO₂) doped with aluminum (Al), hafnium oxide (HfₓO₂) doped with aluminum (Al), Al_{y}ZrₓO₂, or Al_{y}HfₓO₂ (0<x≤1 and 0<y≤1).
